(19) United States
(12) Patent Application Publication
(10) Pub. No.: US 2002/0037025 A1
(43) Pub. Date: Mar. 28, 2002

(54) Hybrid narrow -linewidth semiconductor lasers

(76) Inventors: Randall K. Bartman, Altadena, CA (US); Alexander Ksendzov, La Crescenta, CA (US); Serge Dubovitsky, Los Angeles, CA (US)

Correspondence Address: J. D. Harriman II, COUDERT BROTHERS, 23rd Floor, 333 South Hope Street, Los Angeles, CA, 90071, US

(21) Appl. No.: 09/964,198

(22) Filed: Sep. 25, 2001

Related U.S. Application Data
(60) Provisional application No. 60/235,388, filed on Sep. 25, 2000.

(51) Int. Cl. H01S 3/04; H01S 5/00; H01S 3/08

(52) U.S. Cl. 372/50; 372/96; 372/36

(57) ABSTRACT

The present invention is a method and apparatus for creating a narrow linewidth hybrid semiconductor laser using silicon-oxide and silicone-oxynitride based external feedback elements. These feedback elements use Bragg gratings formed by periodic variation of the refractive index with a resonate optical reflector. The laser has a narrow linewidth (in the tens of kHz range), which can be accurately tunable to facilitate locking to an ultra-stable cavity.

A semiconductor optical gain chip is soldered to a micromachined silicon bench. This semiconductor optical gain chip is coupled into a silicon-oxide/silicon-oxinitride/silicon-oxide (SiO₂/SiON/SiO₂) waveguide terminating in an appropriate feedback element that facilitates linewidth reduction. In order to suppress the loss and scattering at the SiO₂/SiON/SiO₂ interface and due to residual facet reflectance, an antireflection coating is applied. In order to achieve low loss due to mode mismatch, the waveguide modes are tailored to match the gain chip modes.

### RELATED APPLICATION

This application claims the benefit of U.S. Provisional Patent Application No. 60/235,388, filed on Sep. 25, 2000, the disclosure of which is hereby incorporated by reference.

### BACKGROUND OF THE INVENTION

1. Field of the Invention

The present invention relates to the field of lasers, and in particular to a method and apparatus for creating hybrid narrow-linewidth semiconductor lasers.

Portions of the disclosure of this patent document contain material that is subject to copyright protection. The copyright owner has no objection to the facsimile reproduction by anyone of the patent document or the patent disclosure as it appears in the Patent and Trademark Office file or records, but otherwise reserves all rights whatsoever.

2. Background Art

Light amplification by stimulated emission of radiation, or laser, is making roadways in may facets of our daily lives. For example, lasers can be used in alignment applications (to guide machines for drilling tunnels and for laying pipelines), defining targets for military purposes, interforometers (to measure large distances with precision), photography (to simulate a third dimensional depth in holography), medical procedures (to perform surgery on the retina of an eye), communications, and space applications using interferometric metrology and atmospheric spectroscopy, especially in the far infrared 2-3 THz range which requires a very narrow linewidth hybrid semiconductor laser. Even though lasers with very narrow linewidth (10 kHz) are commercially available, they are not tunable over a large range. In order to better understand this limitation of prior art lasers, a thorough understanding of lasers and its various applications are discussed next.

Laser

A laser is any class of devices that produces an intense beam of light of a very pure single color. In principle, atoms and molecules exist at low and high energy levels. Those at low levels can be excited to higher levels, for example by heat, and after reaching the higher levels they give off light when they return to a lower level. In ordinary light sources the many excited atoms and molecules emit light independently and in many different colors (wavelengths). If, however, during the brief instant that an atom is excited, light of a certain wavelength impinges on it, the atom can be stimulated to emit radiation that is in phase (in step) with the wave that simulated it. The new emission thus augments the passing wave; if the phenomenon can be multiplied sufficiently, the resulting beam or laser made up of wholly coherent light, is very intense.

Prior Art Lasers

Depending upon the technique used to create lasers, prior art lasers have a vast range of applications, but they all have limitations and drawbacks that make prior art lasers unsuitable for space exploration applications, and long distance communications, to name a few.

Liquid lasers made, for example, from a solution of neodymium oxide or chloride in selenium oxychloride, and dye lasers made, for example, from rhodamine 6G and methylumbelliferone mixed with hydrochloric acid suffer from the lack of very fine tuning of the laser beam, especially over large distances needed, for example, in space exploration. Even though the dye lasers can be tuned over a side spectral range, they are very flimsy and can be only used under laboratory conditions.

Other lasers, namely the gas discharge lasers which have applications in neon signage, gas dynamic lasers, and chemical lasers not only suffer from the lack of fine tuning of the laser beam, especially over large distances needed, for example, in space exploration, or in situations where a high intensity fine tuned laser beams are needed, but are too bulky and not rugged enough that they have to be handled gently under laboratory conditions. Since the equipment needed to generate these lasers is bulky and occupies a lot of space, it could be critical for certain applications where space and weight conservation are the primary goals.

Optically-pumped solid-state lasers that have applications in metallurgy where the precise cutting of very hard materials is needed, and in mining of minerals has the disadvantage of frequent breakdown and damage at higher power levels because of the intense heat generated within the laser material and by the pumping lamp. This handicap eliminates this kind of laser from applications which are subject to intense temperature variations. The optically-pumped solid-state lasers also suffer from the drawback of a very narrow tuning range of less than 50 GHz.

Free-electron lasers are more efficient than any of the previously mentioned variety in producing laser beams of very high power radiation. Furthermore, these devices are tunable, so that they can be made to operate at microwave to ultraviolet wavelengths. But since the laser beam is generated using free electrons from a particle accelerator or some similar source and passed through an undulator (a device consisting of a linear array of electromagnets), it makes the entire device very bulky and heavy to transport, for example in a module used for space exploration. Furthermore, the entire device has to be kept stationary so that the electromagnets are not influenced by any external forces. These limitations narrow the range of commercial applications for this kind of laser.

Semiconductor lasers are another kind of lasers. Semiconductor lasers consist of a flat junction of two pieces of semiconductor material, each of which are treated with a different type of impurity. When a large electrical current is passed through such a device, laser light emerges from the junction region. This kind of laser suffers from low power output, but the low cost and small size makes these devices suitable for use as light sources, even though it's in a limited commercial market comprising of optical fiber communication and compact digital audio disc players.

R. Kazarinov, C. Henry, and N. Olsson in their paper titled “Narrow-Band Resonant Optical Reflectors and Resonant Optical Transformers for Laser Stabilization and Wavelength Narrow-Division Multiplexing” published in the IEEE Journal of Quantum Electronics (1987), QE-23, on pages 1419 through 1425, and incorporated herein as reference, have proposed a new way of making resonant integrated optical circuits, which are based on a weak side-by-side coupling between waveguides pipelines for the transmittal of the laser light) and high Q distributed Bragg resonators. Using their proposed mathematical calculations, it is possible to create a narrow linewidth hybrid (the coupling of active internal elements that make laser light and passive external elements, for example a Bragg grating written on a waveguide) semiconductor laser. But units made using the narrow-band resonant optical reflector technology proposed by R. Kazarinov, C. Henry, and N. Olsson are not rugged enough for use as communications hardware or in space applications.

Other prior art schemes of making lasers include external elements using silicon and doped silicon dioxide light guides or waveguides with Bragg gratings. Waveguides made with these materials have much larger modes (Modes are specific patterns that the laser light follows. Each waveguide has the ability to propagate a well defined pattern called its waveguide mode) than the standard gain chips (which are the active internal elements that produce the laser light). This necessitates the use of gain chips with mode converters (which are elements that tune the mode of the waveguide so that there is minimal loss of light at the interface of the waveguide and the laser due to mismatch of their respective modes), which are not only expensive, but not readily available.

### SUMMARY OF THE INVENTION

The present invention is a method and apparatus for creating a narrow linewidth hybrid semiconductor laser. According to one embodiment of the present invention, silicon-oxide and silicone-oxynitride based external feedback elements are used to create the laser. According to another embodiment of the present invention, these feedback elements use Bragg gratings with a resonate optical reflector, which is formed by the coupling, and the periodic variation of the refractive index of two Bragg gratings to a main waveguide trunk (path of the laser beam). According to another embodiment of the present invention, the laser is precisely attached to the waveguide by the use of a flip-chip aligner-bonder.

According to one or more embodiments of the present invention, the laser has a narrow linewidth range (tens of kHz range) making it accurately tunable to facilitate locking to an ultra-stable cavity. The hybridization technology achieves narrow linewidth in miniature micromachined units. A semiconductor optical gain chip is soldered to a micromachined silicon bench, and the semiconductor optical gain chip is coupled into a silicon-oxide/silicon-oxinitride/silicon-oxide (SiO₂/SiON/SiO₂) waveguide terminating in an appropriate feedback element, for example, a Bragg grating that facilitates linewidth reduction.

According to other embodiments of the present invention, in order to suppress the loss and scattering of the laser light at the waveguide and laser interface, and due to residual facet reflectance, an antireflection coating is applied to the external feedback elements. According to another embodiment of the present invention, in order to achieve low loss due to mode mismatch, the waveguide is precisely aligned to match the gain chip. The vertical alignment is achieved using micromachined stand-offs, and the horizontal alignment is achieved during the soldering operation using a flip-chip aligner-bonder.

### BRIEF DESCRIPTION OF THE DRAWINGS

These and other features, aspects and advantages of the present invention will become better understood with regard to the following description, appended claims and accompanying drawings where:

FIG. 1 is an illustration of a periodic variation of the refractive index in the core region or cladding of two Bragg gratings.

FIG. 2 is an illustration of a resonant optical reflector.

FIG. 3 is a flowchart illustrating an application of the present invention.

FIG. 4 illustrates a hybridization technique that facilitates precise alignment of a gain chip to a waveguide.

FIG. 5 illustrates a waveguide layout according to one embodiment of the present invention.

### DETAILED DESCRIPTION OF THE INVENTION

The present invention is a method and apparatus for creating a narrow linewidth hybrid semiconductor laser. In the following description, numerous specific details are set forth to provide a more thorough description of embodiments of the invention. It will be apparent, however, to one skilled in the art, that the invention may be practiced without these specific details. In other instances, well known features have not been described in detail so as not to obscure the invention.

The present invention utilizes silicon-oxide and silicon-oxynitride (SiO₂—SiON) based passive external feedback elements that are coupled with the active internal elements to create the narrow linewidth hybrid laser. According to one embodiment of the present invention, these external feedback elements are made to closely match the modes of a standard gain chip. At the same time, using the hybridization technique explained below, the present system enables the fabrication of rugged, reliable lasers for large range and space expanses, for example, deep sea or outer space exploration, and communications. Since these external feedback elements do not need gain chips with mode converters that are expensive and not readily available, the present invention cuts on cost and the time to make a rugged, narrow linewidth laser.

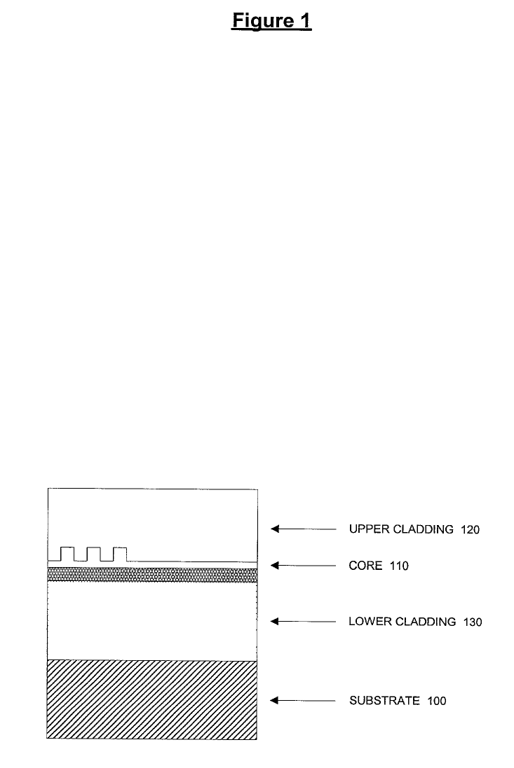

According to another embodiment of the present invention, the external feedback elements use Bragg gratings with a resonate optical reflector, which is formed by the coupling and the periodic variation of the refractive index in the core region or cladding of two Bragg gratings. This is depicted in FIG. 1, where substrate 100 is the bottommost layer followed by lower cladding layer 130. Core 110 is sandwiched between upper cladding 120 and lower cladding 130. The spatial periodic of the modulation is related to the desired center wavelength through an effective mode index.

For example, at 1.5 μm a grating pitch of approximately 0.53 μm is calculated. According to another embodiment of the present invention, in order to produce patterns with such small dimensions, a direct-write electron beam (or e-beam) lithography is used to etch the pattern directly onto the waveguide. In experiments performed using the present invention, a 700-fold linewidth reduction relative to a similar Fabri-Perot laser can be achieved with Bragg gratings. Further reduction in the linewidth can be achieved by using additional resonating structures, one of which is explained below.

Resonant Optical Reflector

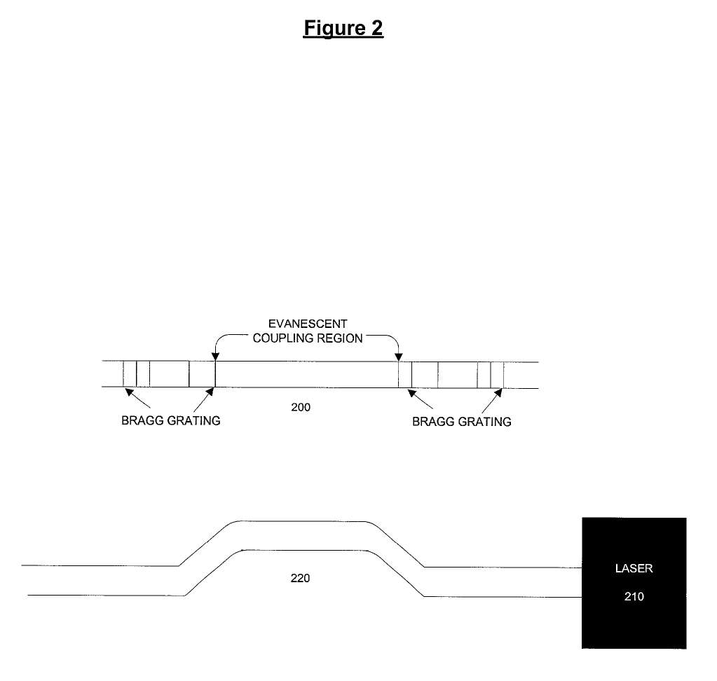

The resonant optical reflector seen in FIG. 2 is a graphical or schematic representation of a resonating structure used to achieve further narrowing of the linewidth, according to another embodiment of the present invention. The resonator formed by the straight waveguide section 200 bounded by two Bragg gratings, which aid in creating the resonator, has a sharp transmittance peak that is converted into a reflectance resonance via a weak coupling of laser 210 to a main curved waveguide trunk 220.

In operation the light from laser 210 is made to flow through the curved waveguide trunk 220. Since the straight waveguide 200 is in such close proximity to the curved waveguide trunk 220, the laser light is coupled onto the straight waveguide, and is depicted by the region marked “evanescent coupling region”. The laser experiences a sharp reflectance peak coinciding with the peak of the resonator, and a narrow linewidth laser is achieved.

Using mathematical calculations developed by R. Kazarinov, C. Henry, and N. A. Olsson (see their paper mentioned in the Background Section), laboratory experiments using the resonant optical reflector external feedback of FIG. 2 resulted in a linewidth reduction of up to 5000 given a waveguide loss of 0.5 dB/cm, mode mismatch loss of 1 dB and interface reflectivity of 3% (0.13 dB).

The present laser posses a narrow linewidth (tens of kHz) that can be accurately tuned. This property of the present invention is crucial to facilitate locking to an ultra-stable cavity for further linewidth reduction. Locking is accomplished by an electronic feedback loop that tunes the laser in response to the wavelength fluctuations away from the cavity resonance. The bandwidth of the feedback loop must be approximately equal to the laser linewidth to properly compensate for the frequency fluctuations. Unlike prior art semiconductor lasers with linewidths above the 100 kHz range that cannot be properly handled by the feedback loop mentioned above since their response to fast (above the 100 kHz range) and slow (below the 100 kHz range) tuning has opposite signs, the present invention does not encounter the same limitations.

According to one embodiment of the present invention, the hybridization technology can achieve the narrow linewidth in miniature micromachined units as well as non-miniature units. This makes the present invention not only conservative in size, but also in weight, which makes it ideal for applications where space and weight are of prime importance, for example in space or deep sea explorations.

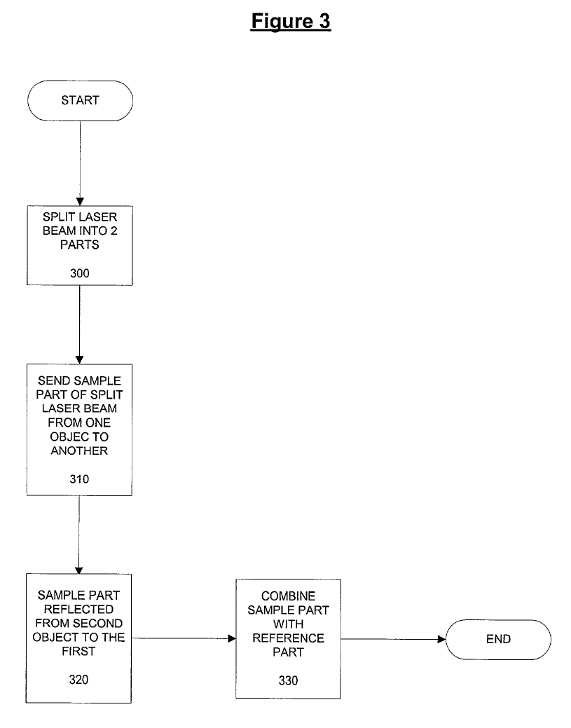

One use of narrow linewidths of the present invention is seen in interferometric metrology. In order to precisely determine the distance between two objects in space, for example two spacecraft, a laser beam, originating from the first object is split in two parts, viz. a reference and a sample part. The sample part of the laser beam is sent from the first object to the second object. This sample part of the laser beam is reflected back to the first object, where it is combined with the reference part. This exercise is illustrated in FIG. 3, where at box 300 a laser beam is split into 2 parts, viz. the reference and sample part. At box 310, the sample part is sent from one object to another. At box 320, the sample part is reflected back from the second object towards the first. At box 330, the return sample part of the laser beam is combined with the reference part.

The intensity of the combined beam depends upon the distance between the two objects and the wavelength of the laser beam. If the distance changes, the maxima and minima will succeed each other as the shift of half wavelengths occurs. In other words, the interference fringes with a period of half wavelength are observed. The distance can therefore be determined by measuring the intensity of the combined beams in relationship to the above mentioned maxima and minima. The present invention can precisely measure the distance between two objects because of two key factors, viz. spectral purity and stability of the laser light source.

Another use of narrow linewidths of the present invention is seen in the generation of terahertz radiation needed for spectroscopic measurements of the upper atmosphere and interstellar gases. Characteristics of a specific gas are measured by using the spectrally narrow absorption peaks seen in the terahertz region of the gas. The measurement requires the fine tuning of a narrow linewidth terahertz source around a specific frequency.

One method used to generate this terahertz radiation is adopted by the present invention where two laser beams are combined on a piece of semiconductor which acts as a mixer. The combine (or beat) frequency, which is the difference between the frequencies of the two laser beams, is generated on the mixer. For this technique to work, not only are two narrow linewidth lasers needed with their radiation frequencies differing by the specific frequency required for the measurement, but a wide tunability is needed for the spectral coverage. Both these requirements are successfully met by the present invention. A narrow linewidth of the two lasers is essential as the combined terahertz source is only as good as the lasers being used for the radiation generation. Even though prior art single narrow linewidth lasers are available which can be used to generate terahertz radiation, pairs of narrow linewidth lasers separated by the necessary frequency interval are not available, and the present invention fills this gap.

Hybridization Process

According to another embodiment of the present invention, the laser is precisely attached to the waveguide by the use of a flip-chip aligner-bonder, which is essentially a microprocessor controlled visible optics system that permits precise alignment and bonding of a flipped die to a substrate. This may be accomplished, for example, by inserting a dual sensor optical probe between the dye and substrate to provide visual images of both the dye and the substrate. Video images from an autocollimator illuminator are superimposed on a video screen permitting visual alignment using, for example, a motorized six axis pitch and roll or a floating/vacuum hold mechanism to position the samples in parallel orientation.

Once the images have been aligned to coincide, the optical probe is withdrawn and the dye and the substrate, now parallel to each other and properly aligned, are brought into contact and bonding is initiated. Preprogrammed pressure and temperature profiles may be followed to ensure proper bonding for the type of contact pads being bonded.

According to one embodiment of the present invention, the flip-chip aligner-bonder uses a technique described by K. A. Cooper, et. al in their paper titled “Flip Chip Equipment For High End Electro-Optical Modules” published in the IEEE Proc. Of ECTC, Seattle, Wash., in May 1998 on page 176, and incorporated herein as reference. Using this technique, the mechanical alignment and placement burdens are borne by a robotic placement machine. Differing substantially from pick and place machines available on the market today, the flip-chip bonder using the technique proposed by K. A. Cooper, et. al. is specifically aimed at the special requirements of the optoelectronic module market, giving special attention to thermal and optical requirements.

The technique described by K. A. Cooper, et. al. accurately assembles high-end optoelectronic modules using a laser diode aligned to a single mode fiber or an optical waveguide, which is soldered to a substrate. The post-bonding alignments of this technique is better than 1 μm for optimum device performance.

According to one or more embodiments of the present invention, a semiconductor optical gain chip is soldered to a micromachined silicon bench. The gain chip and waveguide modes of the present invention are not only tailored to match each other, but precisely aligned. The vertical and horizontal alignments are achieved through the use of micromachined stand-offs and during the soldering operation through the use of a flip-chip aligner-bonder, respectively.

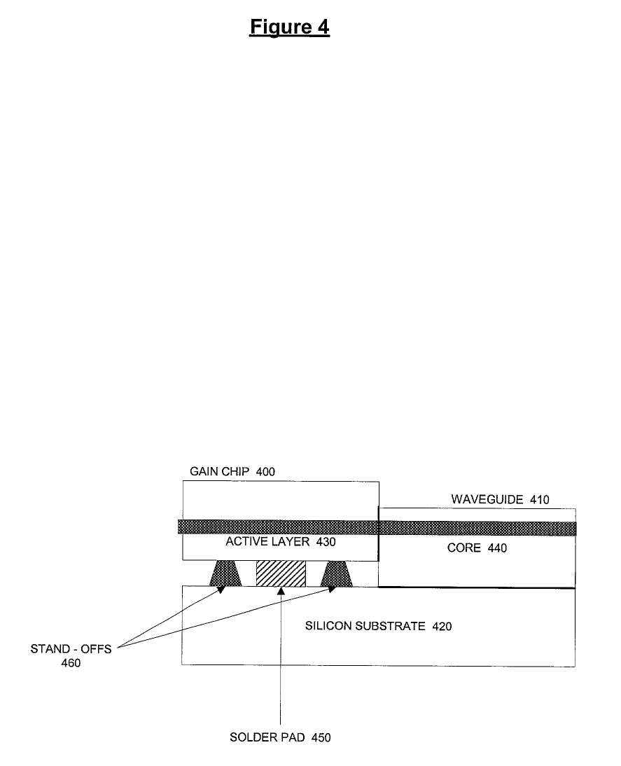

FIG. 4 illustrates a hybridization technique that facilitates precise alignment of the gain chip to the waveguide. Gain chip 400 is coupled with waveguide 410. Both of these are precisely aligned on top of a silicon substrate 420. The alignment is deemed precise once active layer 430 of gain chip 400 is perfectly in line with core 440 of waveguide 410. While the waveguide is aligned directly on top of silicon substrate 420, the gain chip is separated from the silicon substrate by solder pad 450 and stand-offs 460.

In order to achieve a 1 dB coupling loss to a typical gain chip, laboratory tests indicate that using the above mentioned hybridization technique the vertical and horizontal alignment tolerances have to be within±0.2 μm and±1.5 μm respectively. The vertical alignment may be achieved through the use of micromachined stand-offs (element 460 in FIG. 4), while the horizontal alignment may be achieved during the soldering operation through the use of a flip-chip aligner-bonder.

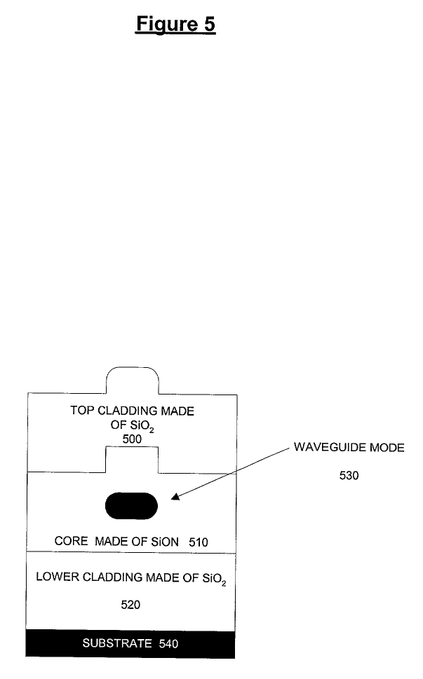

According to another embodiment of the present invention, the semiconductor optical gain chip is coupled into a silicon-oxide/silicon-oxinitride/silicon-oxide (SiO₂/SiON/SiO₂) waveguide terminating in an appropriate feedback element, for example, a Bragg grating that facilitates linewidth reduction. The light guides may be deposited using a technique called the Plasma Enhanced Chemical Vapor Deposition. The waveguide layout using this technique is illustrated in FIG. 5. The top cladding layer 500 and the lower cladding layer 520 are made of silicon-oxide, while the core layer 510 is made of silicon-oxinitride. The waveguide mode 530 is placed in the center of the core layer. The SiO₂/SiON/SiO₂ waveguide is placed on top of substrate 540.

Laboratory tests indicate that the waveguide layout seen in FIG. 5 can be easily modified to achieve good mode match with typical semiconductor gain chips. Similar light guides with low losses of less than 0.5 dB/cm have been achieved during these tests. According to another embodiment of the present invention, in order to reduce the loss and scattering at the SiO₂/SiON/SiO₂ interface and due to residual facet reflectance, a commercially available antireflection coating is applied to the interface.

Thus, a method and apparatus for creating a narrow linewidth hybrid semiconductor laser is described in conjunction with one or more specific embodiments. The invention is defined by the following claims and their full scope of equivalents.

We claim:

1. A method for creating a narrow linewidth hybrid semiconductor laser comprising:
using silicon-oxide and silicon-oxynitride based external feedback elements;
attaching said narrow linewidth hybrid semiconductor laser to a waveguide; and
soldering a semiconductor optical gain chip that acts as the internal element to a micromachined silicon bench.

2. The method of claim 1 wherein said external feedback elements use Bragg gratings.

3. The method of claim 2 wherein said Bragg gratings are formed by the coupling of a first Bragg grating and a second Bragg grating to a main waveguide trunk.

4. The method of claim 3 wherein said first Bragg grating and said second Bragg grating are formed by the periodic variation of the refractive index of said first Bragg grating and said second Bragg grating.

5. The method of claim 1 wherein said narrow linewidth hybrid semiconductor laser is attached to said waveguide by a flip-chip aligner-bonder.

6. The method of claim 1 wherein said narrow linewidth is in the tens of kHz range.

7. The method of claim 1 wherein said narrow linewidth hybrid semiconductor laser is tunable to facilitate locking to a cavity.

8. The method of claim 1 wherein the hybridization method used to create said narrow linewidth hybrid semiconductor laser is achieved in miniature micromachined units.

9. The method of claim 1 wherein said semiconductor optical gain chip is coupled into a silicon-oxide/silicon-oxinitride/silicon-oxide waveguide.

10. The method of claim 9 wherein said waveguide terminates in a feedback element.

11. The method of claim 9 wherein said silicon-oxide/silicon-oxinitride/silicon-oxide interface is coated with an antireflection coating in order to further reduce loss and scattering at said interface.

12. The method of claim 3 wherein said waveguide is tailored to match said gain chip in order to further reduce loss due to mismatch of modes of said waveguide and said gain chip.

13. The method of claim 12 wherein said waveguide and said gain chip are precisely aligned to each other in order to further reduce loss due to mismatch of modes of said waveguide and said gain chip.

14. The method of claim 13 wherein said precise alignment in the vertical direction is achieved through the use of micromachined stand-offs.

15. The method of claim 13 wherein said precise alignment in the horizontal direction is achieved during the soldering operation through the use of said flip-chip aligner-bonder.

16. An apparatus for creating a narrow linewidth hybrid semiconductor laser comprising:
the use of silicon-oxide and silicon-oxynitride based external feedback elements;
said narrow linewidth hybrid semiconductor laser attached to a waveguide; and
a semiconductor optical gain chip soldered to a micromachined silicon bench.

17. The apparatus of claim 16 wherein said external feedback elements use Bragg gratings.

18. The apparatus of claim 17 wherein said Bragg gratings are formed by the coupling of a first Bragg grating and a second Bragg grating to a main waveguide trunk.

19. The apparatus of claim 18 wherein said first Bragg grating and said second Bragg grating are formed by the periodic variation of the refractive index of said first Bragg grating and said second Bragg grating.

20. The apparatus of claim 16 wherein said narrow linewidth hybrid semiconductor laser is attached to said waveguide by a flip-chip aligner-bonder.

21. The apparatus of claim 16 wherein said narrow linewidth is in the tens of kHz range.

22. The apparatus of claim 16 wherein said narrow linewidth hybrid semiconductor laser is tunable to facilitate locking to a cavity.

23. The apparatus of claim 16 wherein the hybridization method used to create said narrow linewidth hybrid semiconductor laser is achieved in miniature micromachined units.

24. The apparatus of claim 16 wherein said semiconductor optical gain chip is coupled into a silicon-oxide/silicon-oxinitride/silicon-oxide waveguide.

25. The apparatus of claim 24 wherein said waveguide terminates in a feedback element.

26. The apparatus of claim 24 wherein said silicon-oxide/silicon-oxinitride/silicon-oxide interface is coated with an antireflection coating in order to further reduce loss and scattering at said interface.

27. The apparatus of claim 18 wherein said waveguide is tailored to match said gain chip in order to further reduce loss due to mismatch of modes of said waveguide and said gain chip.

28. The apparatus of claim 27 wherein said waveguide and gain chip are precisely aligned to each other in order to further reduce loss due to mismatch of modes of said waveguide and said gain chip.

29. The apparatus of claim 28 wherein precise alignment in the vertical direction is achieved through the use of micromachined stand-offs.

30. The apparatus of claim 28 wherein precise alignment in the horizontal direction is achieved during the soldering operation through the use of said flip-chip aligner-bonder.
